(19) United States
(12) Patent Application Publication
(10) Pub. No.: US 2013/0187684 A1
(43) Pub. Date: Jul. 25, 2013

(54) FAST GATE DRIVER FOR SILICON CARBIDE JUNCTION FIELD-EFFECT (JFET) SWITCHING DEVICES

(71) Applicant: RAYTHEON COMPANY, Waltham, MA (US)

(72) Inventor: Robin Gangopadhya, El Segundo, CA (US)

(73) Assignee: RAYTHEON COMPANY, Waltham, MA (US)

(21) Appl. No.: 13/739,175

(22) Filed: Jan. 11, 2013

Related U.S. Application Data
(60) Provisional application No. 61/590,570, filed on Jan. 25, 2012.

(51) Int. Cl. H03K 17/06

(52) U.S. Cl. CPC H03K 17/063
USPC 327/109

(57) ABSTRACT

Devices and techniques are described for selectively driving an electronically controllable switching device between on and off states. A first signal driver provides a respective output selectively switchable between “on” and “off” states responsive to an input signal. A second signal driver likewise provides a respective output selectively switchable between “on” and “off” states responsive to the input signal. Each of the respective outputs is switchable to an overriding isolated state responsive to an enable signal. The outputs are combined at a driving node, such that only one of the outputs drives the node at any given time. Additionally, one of the outputs is coupled to the output node through a current limiting resistor. Accordingly for each switching cycle, the switching device can be pre-charged by a high-current output, then held on for a predetermined period by a controlled-current output, and held off during other periods.

### RELATED APPLICATIONS

The present application claims priority to U.S. Provisional Patent Application No. 61/590,570, filed Jan. 25, 2012, which is incorporated in its entirety herein by reference.

### TECHNICAL FIELD

Various embodiments are described herein relating generally to gate drive circuitry and the like and more particularly to gate drive circuitry for improving operating performance of silicon and silicon-carbide semiconductor devices.

### BACKGROUND

Environmental conditions for military, space exploration or energy exploration applications demand high temperature capable electronics. Such harsh environments pose particular challenges for power electronic systems such as DC-DC converters and inverters requiring operation at high current and fast switching times. Silicon Carbide (SiC) semiconductors are especially valuable in these fields of application due to the SiC material properties. A popular SiC switch is the normally-on JFET that offers larger forward current ratings and lower on resistance.

Silicon semiconductor based gate insulated metal-oxide field effect transistors (IGMOSFET, or in short, MOSFET) are used in many applications in which the gate driver is referenced to a source of the device. Such a configuration requires a floating gate drive scheme. Prior art solutions use a variety of approaches to obtain such a floating nature of the driver. Examples include isolation transfers, opto-isolators and combinations thereof. These approaches work well because they are relatively slow schemes, yet are consistent with the switching speeds of the device technology used.

For a depletion-mode JFET, threshold voltage V_{T} is negative. Consequently, a conducting channel exists between drain and source for zero gate-to-source voltage (i.e., normally “on”). The gate-to-source voltage can, therefore, only be negative or zero to avoid forward biasing the gate-source/drain p-n junction. A negative gate-to-source voltage depletes the channel, pinching it off when V_{GS}≦V_{T}. For gate driver circuits accepting a uni-polar control signal, such as a 0-5V PWM signal, the gate must be isolated

The arrival of ultrafast switching devices, for example, in the form of enhancement mode (EM) silicon-carbide junction FETs (JFET) pose a particular problem. The gate drive has to be floating as in the traditional case described above. However, in addition, the gate drive needs to provide a controlled current to keep the device in an ON state as well as it has to be very fast acting in keeping with the speed of the devices.

Approaches taken by others, such as SemiSouth Laboratories, Inc., a supplier of SiC-JFET devices, use discrete circuitry, for example, including pnp transistors and opto-isolators. Such approaches are relatively slow and do not provide filly for negative side swings of the gate drive across entire range of temperatures.

### SUMMARY

Such a triple problem has been solved by using novel fast isolation devices, as well as a novel arrangement of circuitry described herein to provide controlled current and fast switching.

A circuit and process for driving a control terminal of a semiconductor device includes driving the control terminal to cause the semiconductor device to switch between on (i.e., electrically conducting) and off (i.e., non-conducting) states. The driver circuit responds to an input switching control signal, such as a digital pulse width modulated (PWM) signal. In particular, the driver circuit includes a two-step technique for driving such a switchable device. First, the device is configured to pre-charge a control terminal, such as a gate terminal, of the electronically switchable device by providing a high-current capability to allow for rapid charging. Once charged, the gate is held at in on state by a controlled-current. During off states, the gate is held to an appropriate voltage to ensure that the electronically switchable device is off. For normally on devices, such as SiC devices, a sufficiently negative voltage is provided to turn the device off.

In one aspect, at least one embodiment described herein relates to a system for driving a control input of a semiconductor device. The system includes a first signal driver providing a respective output that is selectively switchable between “on” and “off” states responsive to an input signal. The output is further switchable to an overriding isolated state responsive to an enable signal. A second signal driver provides a respective output that is also selectively switchable between “on” state and “off” states responsive to the input signal. The respective output is similarly switchable to an overriding isolated state responsive to the enable signal. The system also includes a driving node in electrical communication with respective outputs of each of the first and second signal drivers. A gate current limit resistor is provided in electrical communication between the respective output of the first signal driver and the driving node. The system is arranged such that one of the first and second signal drivers is substantially isolated from the driving node at any given time.

In some embodiments, the “off” state results in the driving node being at a sufficiently negative voltage, such that the negative voltage is sufficient to drive a normally-on silicon carbide junction field effect transistor to an “off” state.

In some embodiments, the system includes at least one isolator coupled between each of the first and second signal drivers and an external signal source providing at least one of the input and enable signals. For example, the one or more isolators can include a magneto-resistive device.

In some embodiments, at least one of the first and second signal drivers comprises a high-speed, high-current gate driver, adapted to switch between “on” “off” states in less than about 50 nanoseconds, and to provide a continuous output current of at least about 1 Ampere.

In another aspect, at least one embodiment described herein supports a process for use in driving a control terminal of a semiconductor device. The process includes receiving an input signal variable between “on” and “off” states, such variations between states occurring no sooner than a minimum signal period. An enable signal is received substantially coincident with transitions of the input signal between at least one of the “on” and “off” states. The enable signal is “on” for a pre-charge period substantially that is less than the minimum signal period. A driving node is set to a high-current state during the pre-charge period responsive to the input signal and the enable signal. The driving node is set to a controlled-current state responsive to the input signal and the enable signal for a period after the pre-charge period.

In some embodiments, the process further includes setting the driving node to a negative voltage that when applied to the driving node is sufficient to drive a normally-on silicon carbide junction field effect transistor to an “off” state. In some embodiments, setting the driving node to a high-current state includes enabling a first signal driver for the pre-charge period, while also disabling a second signal driver, such that each of the first and second signal drivers is adapted to drive the gate-drive node.

In some embodiments, setting the driving node to a controlled-current state further includes setting the driving node through a current-limiting resistor. In some embodiments, the process further includes applying the enable signal to a first signal driver, such that the enable signal controls a respective output between enabled and disabled states. The enable signal is inverted and applied to a second signal driver. The inverted enable signal controls a respective output between enabled and disabled states. The process further including applying respective outputs of each of the first and second signal drivers to the gate-drive node.

In another aspect, at least one embodiment described herein relates to a system for driving a control terminal of a semiconductor device. The system includes means for receiving an input signal variable between “on” and “off” states, such variations between states occurring no sooner than a minimum signal period. The system also includes means for receiving an enable signal substantially coincident with transitions of the input signal between at least one of the “on” and “off” states, the enable signal being “on” for a pre-charge period substantially less than the minimum signal period. Means are provided for setting a driving node to a high-current state during the pre-charge period responsive to the input signal and the enable signal. Also provided are means for setting the gate-drive node to a controlled-current state responsive to the input signal and the enable signal for a period after the pre-charge period.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 illustrates a functional block diagram of an embodiment of a semiconductor control terminal driving circuit.

FIG. 2 illustrates examples of various signals within the semiconductor control terminal driving circuit illustrated in FIG. 1.

FIGS. 3A and 3B together illustrate a schematic diagram of an embodiment of a semiconductor control terminal driving circuit.

FIG. 4 illustrates a timing diagram of first and second signal driver input signals and their respective enable signals.

FIG. 5 illustrates a flow diagram of an embodiment of a process for driving a control terminal of a semiconductor device.

FIG. 6 illustrates a schematic diagram of an embodiment of a power conditioning circuit including silicon carbide (SiC) field effect transformer (FET) controlled by a semiconductor control terminal driving circuit.

### DETAILED DESCRIPTION

In the following detailed description of the preferred embodiments, reference is made to accompanying drawings, which form a part thereof, and within which are shown by way of illustration, specific embodiments, by which the invention may be practiced. It is to be understood that other embodiments may be utilized and structural changes may be made without departing from the scope of the invention.

The particulars shown herein are by way of example and for purposes of illustrative discussion of the embodiments of the present invention only and are presented in the case of providing what is believed to be the most useful and readily understood description of the principles and conceptual aspects of the present invention. In this regard, no attempt is made to show structural details of the present invention in more detail than is necessary for the fundamental understanding of the present invention, the description taken with the drawings making apparent to those skilled in that how the several forms of the present invention may be embodied in practice. Further, like reference numbers and designations in the various drawings indicate like elements.

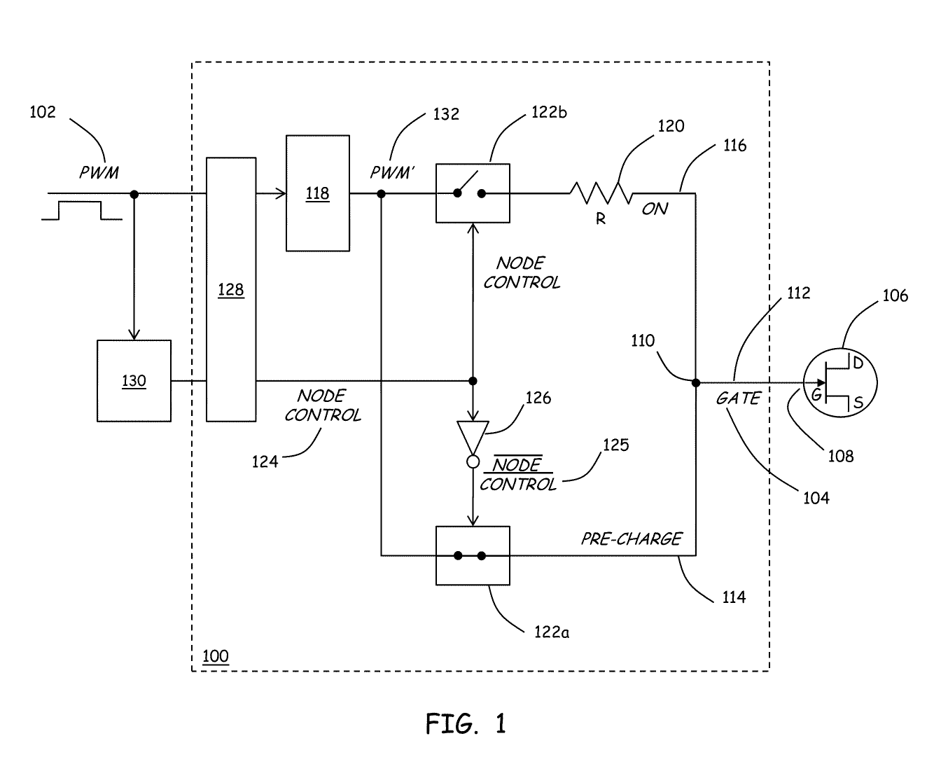

A functional block diagram of an embodiment of a semiconductor control terminal driver circuit 100 is illustrated in FIG. 1. For example, the semiconductor control terminal can be a gate terminal of a semiconductor transistor, such as a field effect transistor. In such applications, the semiconductor control terminal driving circuit can be referred to as a gate driver circuit 100. In the illustrative embodiment, the gate driver circuit 100 receives a switching control signal 102, and in response provides a gate driving signal 104 to a semiconductor switching device 106. In at least some embodiments, the switching device 106 is a semiconductor device, such as a SiC device. In the illustrative example, the semiconductor device is a SiC transistor (e.g., SiC-JFET). For applications driving a SiC-JFET 106, the gate driving signal 104 is applied to a gate terminal 108 of the SiC-JFET 106 device. In operation, the semiconductor switching device 106 turns on and off, either conducting or blocking current. When the switch 106 is on, it conducts current.

The gate driver circuit 100 drives the SiC-JFET 106 between “on” (e.g., closed) or “off” (e.g., open) switching sates according to the received switching control signal 102. For example, when the switching control signal 102 is at a voltage level corresponding to an “on” state, the gate driver circuit 100 provides a gate driving signal 104 that turns the SiC-JFET 106 on. Likewise, when the switching control signal 102 is at a voltage level corresponding to an “off” state, the gate driver circuit 100 provides a gate driving signal 104 that turns the SiC-JFET 106 off The switching control signal 102 can be created via a control board (not shown), for example, with a microprocessor, or with a digital signal processor (DSP), or with some combination of the two.

In the example embodiments described herein, the switching control signals 102 are pulse width modulated (PWM) digital signals. The gate driver circuit 100 processes the received switching control signal 102, subjects it to one or more signal modifying components and circuits (e.g., amplifiers, filters, attenuators, switches, combiners), to obtain the gate driving signal 104. According to proper design, the gate driving signal 104 selectively drives the SiC-JFET 106 into the required “on” and “off” states. For example, in a switching mode application, a voltage level of the switching control signal 102 varies between high and low values, such that transitions in the switching control signal 102 between high and low values correspond to a desired switching of the SiC-JFET 106 (e.g., a high value corresponding to an “on” state and a low value corresponding to an “off” state). The particular voltage levels of the gate driving signal 104 are determined by the SiC-JFET 106, or more generally, by any such device being driven by the gate driver circuit 100. For the SiC-JFET 106, a first voltage can correspond to an “on” state. Likewise, a second voltage can correspond to an “off” state.

The particular high and low signals levels of the received switching control signal are not required to be the same as those of the gate driving signal 104. For example, the voltage levels of the switching control signal 102 can comply with a particular hardware design protocol as may be used in generating the signal 102. For example, the switching control signal 102 can operate according to logic signal voltage levels. Some common logic signal voltage levels include transistor-transistor logic (TTL) (e.g., high=2-5V, low=0-0.8V) and complementary metal-oxide-semiconductor logic (CMOS) (e.g., high=3.5-5V, low=0-1.5V). Other logic families include emitter-coupled logic (ECL), including positive emitter-coupled logic (PECL) and low-voltage positive emitter-coupled logic (LVPECL), bipolar complementary metal-oxide-semiconductor (BiCMOS) and integrated injection logic (I²L). In general, there are no restrictions on the particular voltage levels of the input switching control signal 102.

In the illustrative embodiment, the gate driving signal 104 is determined at least in part by the voltage and current conditions at a gate driving node 110. The node 110 is formed at an intersection of three circuit branches. A first branch 112 is coupled between the node 110 and the gate terminal 108. A second branch 114 is coupled between the node 110 and a signal conditioning circuit 118. A third branch 116 is also separately coupled between the node 110 and the signal conditioning circuit 118. The third branch 116 is distinguishable from the second branch 114 at least in that it includes a series-coupled, current-limiting resistor 120 having a value of R Ohms. A first isolation switch 122a is coupled in series along the second branch 114, between the signal conditioning circuit 118 and the node 110. A second isolation switch 122b is similarly coupled in series along the third branch 116, between the signal conditioning circuit 118 and the node 110. (The series coupled resistor 120 can be located along either side of the second switch 122b.) Each of the isolation switches 122a, 122b (generally 122) is a single pole, single throw switch, in that each isolation switch 122 is operable to open-circuit, or otherwise drive its respective branch 114, 116 to a high impedance state in response to a node control signal 124. Either isolation switch 122 being isolated (e.g., open circuit) effectively isolates or otherwise removes the respective branch 114 from the node 110. A branch 114, 116 being isolated in this manner will contribute an insignificant current, if any, to the gate driving signal 104.

In the example embodiment, the node control signal (NODE CONTROL) 124 is coupled to a control terminal of the second isolation switch 122b. The same node control signal 124 is coupled to an input of an inverter 126. An output terminal of the inverter 124, providing an inverted version of the input signal 125 is coupled to a control terminal of the first isolation switch 122a. In operation, the node control signal 124 substantially simultaneously closes one isolation switch (e.g., the first isolation switch 122a) while opening the other isolation switch (e.g., switch 122b). Thus, only one of the circuit branches 114, 116 is effectively driving the node 110 at any given instant of time, the other circuit branch being in a high-impedance state (e.g., “open circuited”).

The signal conditioning circuit 118 receives the switching control signal 102 and conditions the signal 102 in preparation for driving the gate terminal 108 of the SiC-JFET 106. The signal conditioning circuit 118, for example, can perform one or more of signal amplification, attenuation, filtering and level offset to the switching control signal 102. In the example embodiment in which the SiC-JFET 106 is normally on, it is desirable that the signal conditioning circuit 118 provide a level offset for a logic-based switching control signal 102. In particular, the level offset results in a conditioned switching control signal (PWM′) 132 that is sufficiently negative during an “off” portion of the switching control signal 102, such that the gate terminal 108 of the SiC-JFET 106 is driven to an “off” state (i.e., providing a negative gate-to-source voltage that is below a threshold voltage (i.e., V_{GS}≦V_{T}), such that the applied voltage depletes the channel of the SiC-JFET 106, pinching it off).

In at least some embodiments, the gate driver circuit 100 includes an isolator 128. The isolator 128 isolates a source of the gate driving signal 104 (e.g., external circuitry) from the gate terminal 108 of the SiC-JFET device 106. The isolator 128 can include one or more circuit elements commonly used in isolating circuits, such as isolation transformers and optical-isolators. In at least some embodiments, the isolator 128 includes a giant magneto resistive (GMR) isolator. GMR isolators are devices particularly well suited for high-temperature applications.

In operation, the switching control signal 102 and node control signal 124 originating from external sources are received at the isolator 128. As illustrated, the node control signal 124 can be derived from the switching control signal 102 by a logic circuit. Alternatively or in addition, the node control signal 124 can be provided by a digital signal processor (DSP) 130. The DSP 130 can be external to the gate driver circuit 100 as shown; however, it is understood that such logic circuits (e.g., DSP 130) can be included within the gate driver circuit 100. An isolated version of the switching control signal 102, still at digital signal levels (e.g., 0-5V) is input to the signal conditioning circuitry 118. In the example embodiment, signal conditioning includes a level adjust such that a low voltage value (e.g., a 0V for the switching control logic level “low”) is sufficiently level adjusted to a negative voltage value, to reliably turn off the SiC-JFET 106. The appropriately conditioned switching control signal (PWM′) 132 is split and provided to each of the second and third legs 114, 116 of the gate driver circuit 100.

The conditioned switching control signal 132 is routed from the signal conditioning circuit 118 through a second isolation switch 122b and through the current control resistor 120 in the third leg 116; whereas, the same signal 132 is routed through the first isolation switch 122a of the second leg 114 and directly to the gate driving node 110. A signal routed through the second leg 114 is referred to herein as a PRE-CHARGE signal, indicating that can be applied to the gate terminal 108 of the SiC-JFET in order to pre-charge the gate terminal 108. A signal routed through the third leg 116 is referred to herein as an ON signal, indicating that can be applied to the gate terminal 108 of the SiC-JFET during a current-controlled “on” period of driving the gate terminal 108. Whichever signal is applied to the node 110 (PRE-CHARGE, ON), depends upon which of the first and second isolation switches 122a, 122b is closed. The inverter 126 ensures that each isolation switch 122a, 122b receives an inverted version of the node control signal 124, such that the isolation switches 122a, 122b are substantially controlled to opposite states (i.e., open, closed) at any given instant of time.

In at least some embodiments, the first isolation switch 122a is closed and the second isolation switch is open 122a responsive to an “on” (e.g., high) signal level of the switching control signal 102. Thus, the conditioned switching control signal 132 is routed directly to the gate driving node 110, allowing the conditioned switching control signal 132 to charge the gate terminal 108 of the SiC-JFET 106, during a pre-charging period. Since there is minimal resistance drop in the second leg 114 (i.e., minimal loss due to finite conductivity of any realizable circuit traces), the node 110 can be supplied with a relatively high current, depending upon loading by the gate terminal 108. As such, the relatively high current allows the gate terminal 108 to charge relatively quickly.

After the pre-charging period, the node control signal 124 changes state, such that the first isolation switch 122a opens as the second isolation switch 122b closes. Thus, the conditioned switching control signal 132 is routed to the gate driving node 110 through the current-limiting resistor 120. The current-limiting resistor 120 allows the signal 132 to drive the gate terminal 108 of the SiC-JFET 106 with a controlled current. The current value can be controlled at least in part according to a selected resistance value R of the current-limiting resistor 120. Thus, the second branch 114 can be said to provide a pre-charge signal, whereas, the third branch 110 can be said to provide a controlled current signal. The currents in each of the first, second and third legs 112, 114, 116 sum at the node 110, such that the gate driving signal (GATE) 104 results from a combination of the PRE-CHARGE signal and the ON (i.e., controlled current) signal.

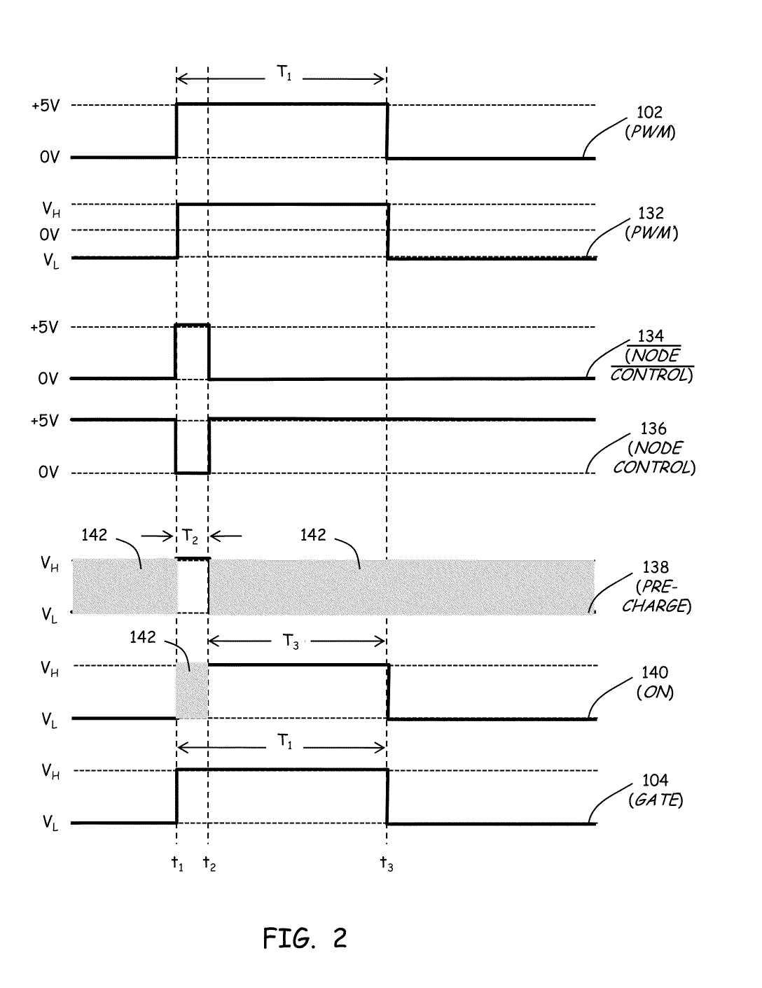

Illustrated in FIG. 2, are examples of the various signals described in relation to the gate driving circuit 100 illustrated in FIG. 1. An example of a switching control signal (PWM) 102 is shown as a digital signal, varying between representative voltage levels of 0V (i.e., “low”) and 5V (i.e., “high”). Initially, the PWM signal 102 is in a low state. At time t₁, the PWM signal 102 transitions to a high state and remains there for a duration of time (i.e., between times t₁ and t₃) represented by period T₁, after which it returns to a low state. In the illustrative embodiments described herein, the gate driver circuit 100 responds to the PWM signal 102 by driving the gate terminal 108 of the SiC-JFET device 106, such that the device 106 is off (i.e., non-conducting) at times before t₁ and after t₃, and on (i.e., conducting) at times substantially between t₁ and t₃.

In at least some embodiments, the device 106 is driven on approximately between times t₂ and t₃. The initial period between times t₁ and t₂ establishes a pre-charging of the gate terminal 108 of the device 106, that concludes when the gate terminal 108 has been charged sufficiently to turn on the device 106. The duration of such a pre-charging period can be determined for a given device 106 to be driven. Taking into account the pre-charging period, it is understood that in at least some embodiments, the gate driving signal 104 is lengthened by a corresponding amount, such that the device 106 is turned on for a duration corresponding to the pulse width of the PWM signal 102.

Also shown is an example of a conditioned switching signal PWM′ 132. The PWM′ signal 132 is similarly at a low state before time t₁ and after time t₃ and at a high state between times t₁ and t₃ (not accounted for in the illustrative example are lags between transitions of the PWM signal 102 and the PWM′ signal 132, as well as non-ideal rise and fall times). Most notably, the PWM′ signal 132 varies between different voltage levels represented by V_{L} corresponding to a low state and V_{H} corresponding to a high state. In general, the particular low and high signal levels V_{L}, V_{H}, correspond to voltage levels sufficient to drive the switching device (in the example embodiment, the SiC-JFET device 106) between off and on states. As indicated above, the SiC-JFET 106 is normally on, such that a negative voltage V_{L} is required to turn the device 106 off. As illustrated, the low state voltage V_{L} can be negative. The high state voltage can be positive, as indicated, or also negative, but at a lower value (i.e., |V_{H}|<|V_{L}|).

An example of a node control signal 136 is shown having an initially high state, transitioning to a low state at time t₁ and returning to a high state at time t₂. As illustrated, time t₂ is between times t₁ and t₃. In the illustrative embodiment, the node control signal 136 is a logic signal, also extending between 0-5V. It is understood that in some embodiments, different high and low voltage levels can be used, as may also correspond to logic levels.

An example of a pre-charging PRE-CHARGE signal 138 is initially in a high-impedance state 142 at times before time t₁. The PRE-CHARGE signal 138 transitions to non-high impedance state between time t₁ and time t₂, for a period of time represented by T₂. After time t₃, the PRE-CHARGE signal 138 once again transitions to a high-impedance state 142. In the illustrative example, the PRE-CHARGE signal 138 is at a high signal state between time t₁ and time t₂ corresponding to the state of the PWM signal 102.

An example of a controlled-current ON signal 140 is initially in a low state at times before time t₁. The ON signal 140 transitions to high-impedance state 142 between time t₁ and time t₂, for a period of time represented by T₂. After time t₃, the ON signal 140 transitions to a high state corresponding to the state of the PWM signal 102. In the illustrative example, the ON signal 140 is at a high state between time t₂ and time t₃ for a period of time represented by T₃. After time t3, the ON signal 140 transitions to a low state, once again following the state of the PWM signal 102.

An example of a gate driving GATE signal 104 is also illustrated in FIG. 2. The GATE signal 104 has a form substantially following the form of the conditioned switching control signal 132. Namely, the GATE signal 104 is initially at a low state until it transitions to a high state at time t₁. The GATE signal 104 remains at the high state for a period T₁ until it transitions again to a low state at time t₃. It is worth noting that the signals represented herein are illustrated for the purposes of comparison and to provide a general understanding basic operation of the devices and techniques described herein. As such, the signals do not account for lags as may be experienced between the various signals (e.g., resulting from gate delays), as well as non-ideal rise and fall times, and the like.

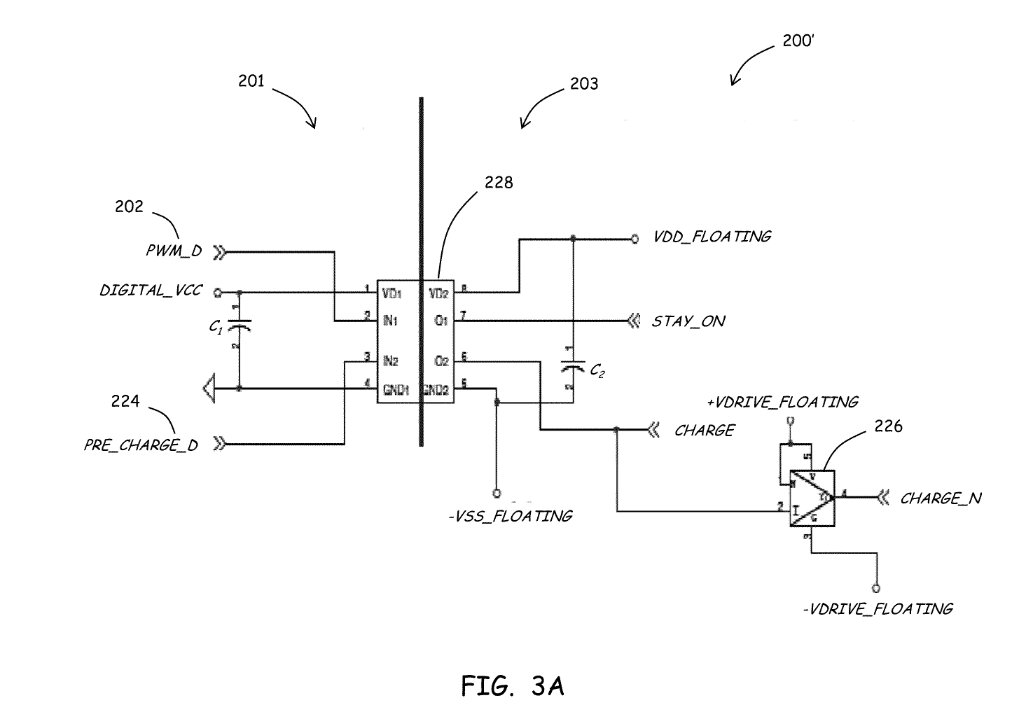

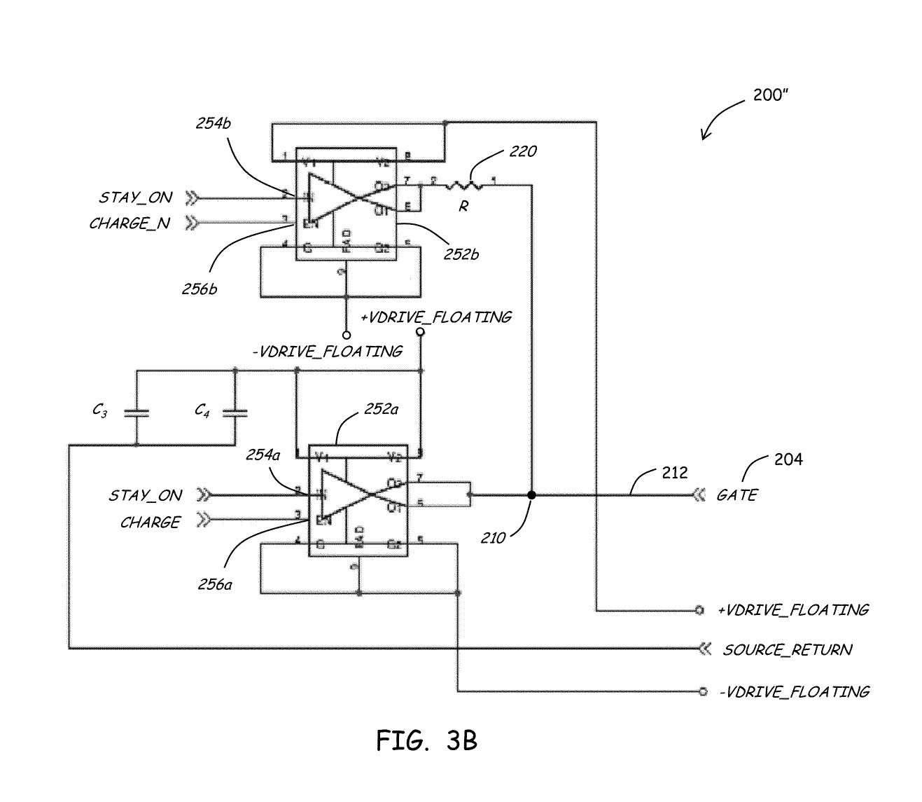

FIGS. 3A and 3B together illustrate a schematic diagram of an embodiment of a gate driver circuit 200 (a first portion of the circuit 200′ illustrated in FIG. 3A and a second portion of the circuit 200″ illustrated in FIG. 3B). The circuit 200 includes a signal isolator 228 dividing the circuit into a digital signal portion 201, shown to the left of the signal isolator 228, and a floating signal portion 203, shown to the right of the signal isolator 228. A vertical line has been drawn through the signal isolator 228 to signify a demarcation between non-isolated 201 and isolated 203 portions of the circuit 200.

Preferably, the signal isolator 228 is an ultrafast isolating device, such as a GMR isolating device. The signal isolator 228 receives at respective input terminals digital implementations of the switching control signal 102 and a node control signal 124, referred to herein as PWM_D signal 202 and PRE_CHARGE_D signal 224. The signal isolator 228 also receives a digital power supply input DIGITAL_VCC (referenced to ground) as well as floating power supply inputs VDD_FLOATING and −VCC_FLOATING. In at least some embodiments, respective filter capacitors C₁ and C₂ can be provided in parallel across each of the power supply inputs.

The isolator 228 provides an output signal STAY_ON that corresponds to an isolated representation of the PWM_D signal 202. Likewise, the isolator 228 also provides an output signal CHARGE that corresponds to an isolated representation of the PRE_CHARGE_signal 224. The circuit 200 also includes an inverter 226 receiving the CHARGE signal at an input terminal and providing at an output terminal an inverted representation CHARGE_N of the signal. In the illustrative embodiment, the inverter 226 is powered by floating power supply voltages +VDRIVE_FLOATING and −VDRIVE_FLOATING.

Continuing with the illustrative embodiment, the gate driver circuit 200 includes first and second signal drivers 252a, 252b (collectively referred to as 252). Each of the signal drivers 252 is powered by the floating power supply voltages +VDRIVE_FLOATING and −VDRIVE_FLOATING. Each of the signal drivers 252 has a respective signal input terminal 254a, 254b and a respective enable terminal 256a, 256b. When enabled, each driver 252 provides a respective output that is a representation of its respective input signal (i.e., STAY_ON) as long as the driver 252 is enabled. When the driver 252 has not been enabled, the output is held at a high impedance state regardless to any input value. In some embodiments, at least one of the first and second signal drivers includes a high-speed, high-current gate driver, adapted to switch between “on” “off” states in less than about 50 nanoseconds, and to provide a continuous output current of at least about 1 Ampere.

In the illustrative example, the driver 252 provides signal conditioning by ensuring that any representation of the STAY_ON signal provided as an output resides between the isolated power supply voltages (i.e., between +VDRIVE_FLOATING and −VDRIVE_FLOATING). In at least some embodiments, the floating power supply voltages can be selected to ensure that the switching device 106 is driven to an “on” state for a high voltage state (e.g., +VDRIVE_FLOATING) and that the switching device 106 is driven to an “off” state for a low voltage state (e.g., −VDRIVE_FLOATING). Thus, each driver 25,2 as shown, can be configured to perform dual functions of signal conditioning and selective signal isolation, as otherwise provided by the signal conditioning circuitry and isolation switches 122 described in relation to FIG. 1.

The output of the first signal driver 252a is coupled to a summing node 210. The output of the second signal driver 252b is also coupled to the summing node 210 through a series coupled resistor 220. The summing node 210 is further coupled to an output signal trace 212 providing the GATE signal 204. The output signal trace 212 can be connected to a control terminal, such as a gate terminal of the switching device 106. Once again, filter capacitors C₃, C₄ can be provided with respect to the isolated power supply input.

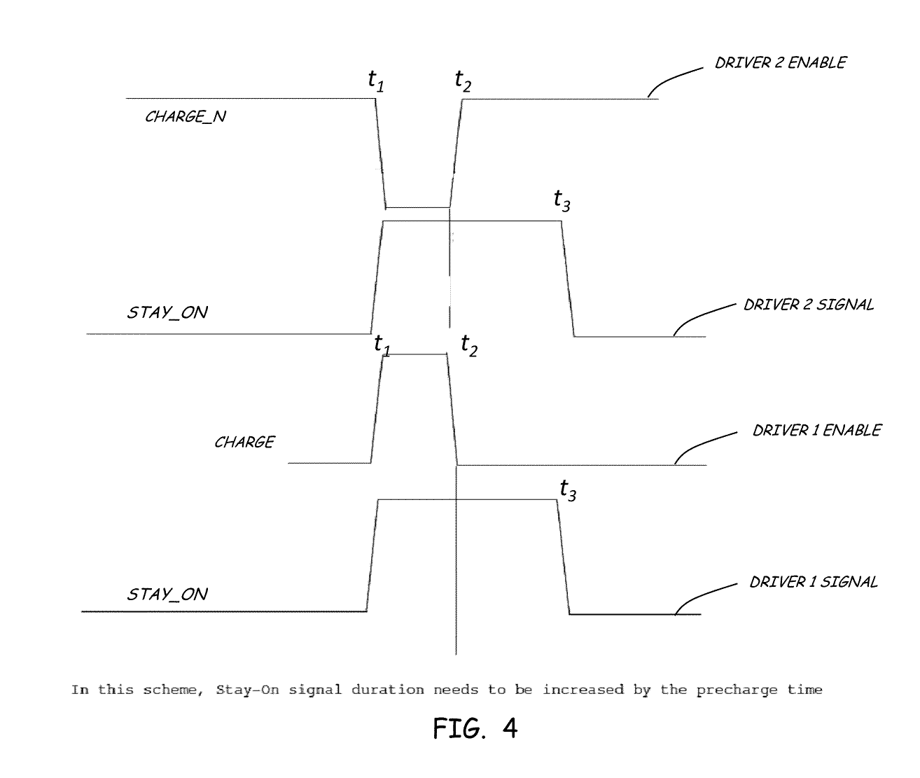

Illustrated in FIG. 4, is a more detailed timing diagram of first and second driver output signals and their respective enable signals for the signal driver circuit of FIGS. 3A and 3B. The isolated switching control signal STAY_ON is provided to input terminals 254a, 254b of each signal driver 252a, 252b. The CHARGE signal is provided to the enable terminal 256a of the first signal driver 256a. The inverted signal CHARGE_N is provided to the enable terminal 256b of the second signal driver 252b.

While the enable terminal 256a of the first driver 252a is low, an output of the first driver 252a is in a high-impedance state. When the enable terminal 256a of the first driver 252a is high, an output of the first driver 252a follows the input signal STAY_ON. Thus, for the period between t₁ and t₂ (e.g., about 150 nanoseconds), the output of the first driver 252a follows STAY_ON signal. At all other times, the output of the first driver 252a is in a high-impedance state. While the enable terminal 256b of the second driver 252b is low, an output of the second driver 252b is in a high-impedance state. When the enable terminal 256b of the second driver 252b is high, an output of the second driver 252b follows the respective driver's input signal STAY_ON. Thus, for the period between t₁ and t₂, the output of the second driver 252b is in a high-impedance state. At all other times, the output of the second driver 252b follows STAY_ON signal. In the illustrative example, a switching device driven by the gate driver circuit 200 is on for as long as the STAY_ON signal is high. Understanding that the switching device may not be no during any pre-charging period, it is understood that in at least some embodiments, the STAY_ON signal duration (e.g., pulse width) is increased over the original PWM input signal by an amount corresponding to the pre-charging period.

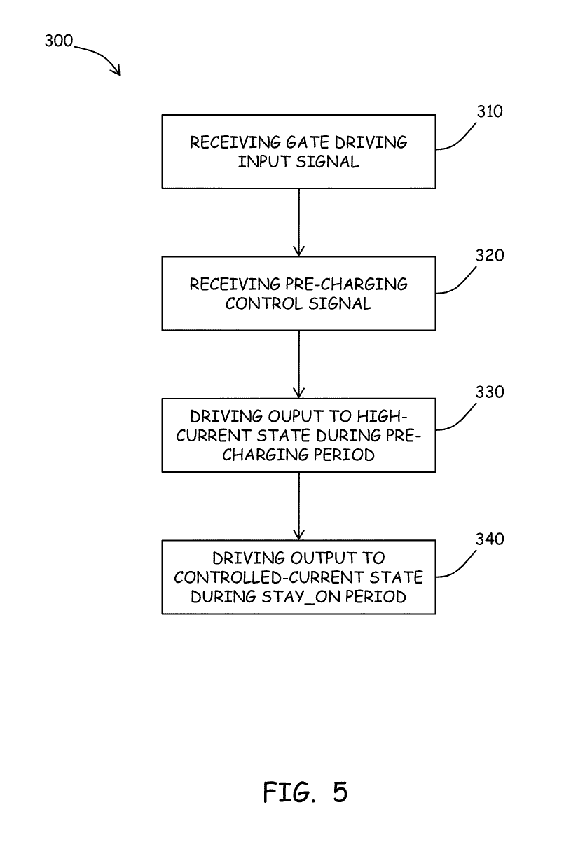

A flow diagram of an embodiment of a process 300 for driving a switching device, such as a gate terminal of a silicon carbide (SiC) field effect transformer (FET) is illustrated in FIG. 5. A gate driving input signal is received at 310. The gate driving input signal is indicative of periods during which the switching device should be switched on or off. For example, the gate driving input signal can be a digital, pulse width modulated signal, such that the switching device should be on (i.e., conducting) during high signal levels and off (i.e., non-conducting) during low signal levels.

A pre-charging control signal is received at 320. The pre-charging control signal is indicative of periods during which the switching device should be operated in a pre-charging mode. A pre-charging mode can include modes of operation in which a relatively high value of electrical current is supplied to the device. A switching control output (i.e., an output of a gate driver circuit) is driven to a high-current state in response to the pre-charging control signal at 330. Such high-current modes can be advantageous, for example, for rapidly charging a gate terminal of a SiC FET device. Such high-current modes may not be advantageous during other periods of operation after which the switching device (i.e., the gate terminal of the SiC-FET device). Such uncontrolled current mode operation can lead to operation of a switching device outside of its intended operating parameters resulting in unreliable operation and in some instances, device damage.

During all times other than pre-charging, the switching control output is driven to a controlled-current at 340 according to the gate driving input signal. Thus, when the gate driving input signal indicates that the switching device should be on, and the switching device is not being operated in a pre-charging mode, the switching control output is driven to a controlled-current value. Such a controlled-current value can be selected, for example, to ensure that the switching device is driven to a desired state. For semiconductor switching devices, such as the SiC JFET devices described herein, the controlled-current values are chosen such that the device is operated within its intended design tolerances. When the gate driving input signal indicates that the switching device should be off, the switching control output is driven such that the controlled switching device is driven to an off state.

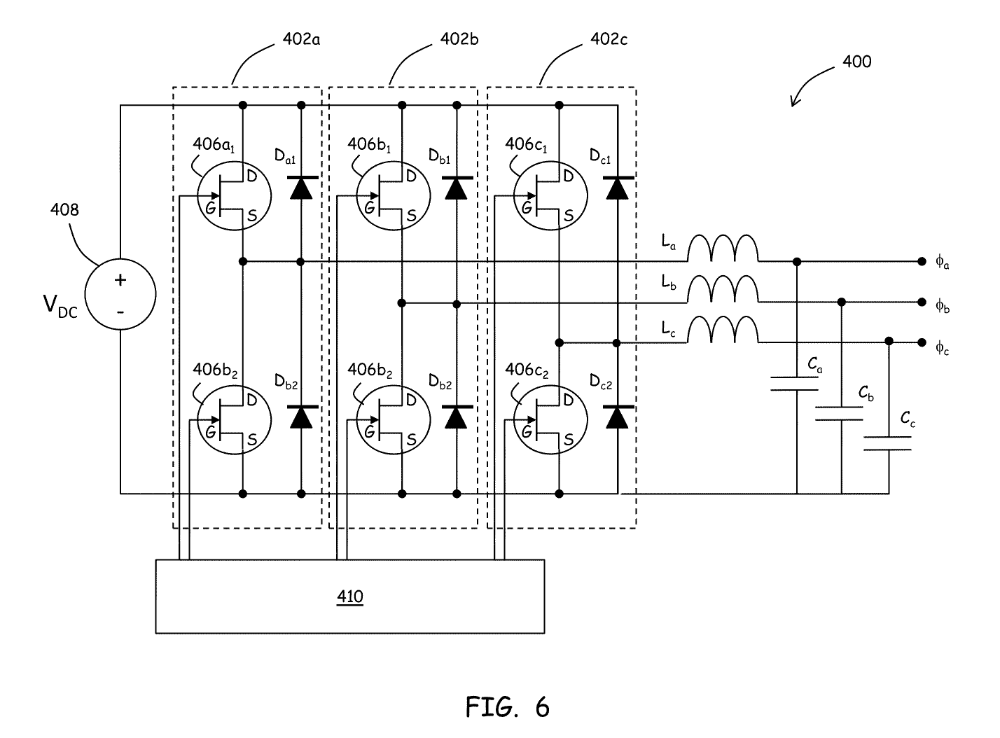

FIG. 6 illustrates a schematic diagram of an embodiment of a power conditioning circuit 400 including SiC-FET switches. The power conditioning circuit 400 converts a direct current (DC) voltage V_{DC} into three-phase alternating current, denoted by phase outputs φₐ, φ_{b} and φ_{c}. The power conditioning circuit 400 includes three circuit legs 402a, 402b, 402c (collectively 402), each leg 402 corresponding to a respective one of the three ac phases φₐ, φ_{b} and φ_{c}. Each leg 402 is constructed similarly. With respect to the first leg 402a, a pair of series coupled diodes D_{α1}, D_{α2}, is coupled across V_{DC}, with the diodes being coupled anode to cathode. A first switching device 406a₁ is coupled in parallel with the first diode D_{α1}, and a second switching device 406a₂ is coupled in parallel with the second diode D_{α2}. For each circuit leg 402, one end of a phase-leg inductor La is coupled between the series coupled diodes D_{α1}, D_{α2} of the respective circuit leg 402a and a respective phase output terminal φₐ. For each circuit leg 402, a respective filter capacitor Ca is coupled between the phase output terminal φₐ and the negative terminal of the DC supply 408. Each of the second and third current legs is configured similarly.

A gate driver circuit 410 is coupled to each of the current switching devices 406a, 406b of each of the respective circuit legs 402. In operation, the gate driver circuit 410 drives the current switching devices 406a, 406b to provide gate driving signals to each of the switching devices 406a, 406b of each leg 402 to sequentially produce positive and negative portions of an AC cycle. An L-C filter provided by the leg inductor La and capacitor Ca provide a desired filtering effect to produce a filtered AC cycle of a three-phase system. The gate driver circuit 410 provides similar control signals to the other legs with a pre-determined delay (e.g., 120 deg.) to provide a suitable three-phase AC output signal. The gate driver circuit 410 controls each of the switching devices 406a, 406b according to the techniques described herein and equivalents thereto.

The above-described systems and processes can be implemented in digital electronic circuitry, in computer hardware, firmware, and/or software. The implementation can be as a computer program product (i.e., a computer program tangibly embodied in an information carrier). The implementation can, for example, be in a machine-readable storage device and/or in a propagated signal, for execution by, or to control the operation of, data processing apparatus. The implementation can, for example, be a programmable processor, a computer, and/or multiple computers.

A computer program can be written in any form of programming language, including compiled and/or interpreted languages, and the computer program can be deployed in any form, including as a stand-alone program or as a subroutine, element, and/or other unit suitable for use in a computing environment. A computer program can be deployed to be executed on one computer or on multiple computers at one site.

Method steps can be performed by one or more programmable processors executing a computer program to perform functions of the invention by operating on input data and generating output. Method steps can also be performed by and an apparatus can be implemented as special purpose logic circuitry. The circuitry can, for example, be a FPGA (field programmable gate array) and/or an ASIC (application-specific integrated circuit). Modules, subroutines, and software agents can refer to portions of the computer program, the processor, the special circuitry, software, and/or hardware that implements that functionality.

Processors suitable for the execution of a computer program include, by way of example, both general and special purpose microprocessors, and any one or more processors of any kind of digital computer. Generally, a processor receives instructions and data from a read-only memory or a random access memory or both. The essential elements of a computer are a processor for executing instructions and one or more memory devices for storing instructions and data. Generally, a computer can include, can be operatively coupled to receive data from and/or transfer data to one or more mass storage devices for storing data (e.g., magnetic, magneto-optical disks, or optical disks).

Data transmission and instructions can also occur over a communications network. Information carriers suitable for embodying computer program instructions and data include all forms of non-volatile memory, including by way of example semiconductor memory devices. The information carriers can, for example, be EPROM, EEPROM, flash memory devices, magnetic disks, internal hard disks, removable disks, magneto-optical disks, CD-ROM, and/or DVD-ROM disks. The processor and the memory can be supplemented by, and/or incorporated in special purpose logic circuitry.

To provide for interaction with a user, the above described techniques can be implemented on a computing device having a display device. The display device can, for example, be a cathode ray tube (CRT) and/or a liquid crystal display (LCD) monitor, and/or a light emitting diode (LED) monitor. The interaction with a user can, for example, be a display of information to the user and a keyboard and a pointing device (e.g., a mouse or a trackball) by which the user can provide input to the computing device (e.g., interact with a user interface element). Other kinds of devices can be used to provide for interaction with a user. Other devices can, for example, be feedback provided to the user in any form of sensory feedback (e.g., visual feedback, auditory feedback, or tactile feedback). Input from the user can, for example, be received in any form, including acoustic, speech, and/or tactile input.

The above described techniques can be implemented in a distributed computing system that includes a back-end component. The back-end component can, for example, be a data server, a middleware component, and/or an application server. The above described techniques can be implemented in a distributing computing system that includes a front-end component. The front-end component can, for example, be a client computing device having a graphical user interface, a Web browser through which a user can interact with an example implementation, and/or other graphical user interfaces for a transmitting device. The components of the system can be interconnected by any form or medium of digital data communication (e.g., a communication network). Examples of communication networks include a local area network (LAN), a wide area network (WAN), the Internet, wired networks, and/or wireless networks.

The system can include clients and servers. A client and a server are generally remote from each other and typically interact through a communication network. The relationship of client and server arises by virtue of computer programs running on the respective computing devices and having a client-server relationship to each other.

Communication networks can include packet-based networks, which can include, for example, the Internet, a carrier internet protocol (IP) network (e.g., local area network (LAN), wide area network (WAN), campus area network (CAN), metropolitan area network (MAN), home area network (HAN)), a private IP network, an IP private branch exchange (IPBX), a wireless network (e.g., radio access network (RAN), 802.11 network, 802.16 network, general packet radio service (GPRS) network, HiperLAN), and/or other packet-based networks. Circuit-based networks can include, for example, the public switched telephone network (PSTN), a private branch exchange (PBX), a wireless network (e.g., RAN, bluetooth, code-division multiple access (CDMA) network, time division multiple access (TDMA) network, global system for mobile communications (GSM) network), and/or other circuit-based networks.

The computing device can include, for example, a computer, a computer with a browser device, a telephone, an IP phone, a mobile device (e.g., cellular phone, personal digital assistant (PDA) device, laptop computer, electronic mail device), and/or other communication devices. The browser device includes, for example, a computer (e.g., desktop computer, laptop computer) with a World Wide Web browser (e.g., Microsoft® Internet Explorer® available from Microsoft Corporation, Mozilla® Firefox available from Mozilla Corporation). The mobile computing device includes, for example, a Blackberry®.

Comprise, include, and/or plural forms of each are open ended and include the listed parts and can include additional parts that are not listed. And/or is open ended and includes one or more of the listed parts and combinations of the listed parts.

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes that come within the meaning and range of equivalency of the claims are therefore intended to be embraced therein.

What is claimed is:

1. A gate drive circuit, comprising:
a first signal driver providing a respective output selectively switchable between “on” and “off” states responsive to an input signal, the respective output switchable to an overriding isolated state responsive to an enable signal;
a second signal driver providing a respective output selectively switchable between “on” state and “off” states responsive to the input signal, the respective output switchable to an overriding isolated state responsive to the enable signal;
a driving node in electrical communication with respective outputs of each of the first and second signal drivers; and
a gate current limit resistor in electrical communication between the respective output of the first signal driver and the driving node, one of the first and second signal drivers is substantially isolated from the gate-drive node at any given time.

2. The gate drive circuit of claim 1, wherein at least one of the input and enable signals is a digital signal.

3. The gate drive circuit of claim 1, wherein the “off” state results in the driving node being at a sufficiently negative voltage, such that the negative voltage is sufficient to drive a normally-on silicon carbide junction field effect transistor to an “off” state.

4. The gate drive circuit of claim 1, further comprising at least one isolator coupled between each of the first and second signal drivers and an external signal source providing at least one of the input and enable signals.

5. The gate drive circuit of claim 4, wherein the at least one isolator comprises a magneto-resistive device.

6. The gate drive circuit of claim 1, further comprising an inverter in electrical communication with one of the first and second signal drivers, the inverter configured to invert the enable signal.

7. The gate drive circuit of claim 1, wherein at least one of the first and second signal drivers comprises a high-speed, high-current gate driver, adapted to switch between “on” “off” states in less than about 50 nanoseconds, and to provide a continuous output current of at least about 1 Ampere.

8. A method for driving a control terminal of a semiconductor device, the method comprising:
receiving an input signal variable between “on” and “off” states, such variations between states occurring no sooner than a minimum signal period;
receiving an enable signal substantially coincident with transitions of the input signal between at least one of the “on” and “off” states, the enable signal being “on” for a pre-charge period substantially less than the minimum signal period;
setting a driving node to a high-current state during the pre-charge period responsive to the input signal and the enable signal; and
setting the gate-drive node to a controlled-current state responsive to the input signal and the enable signal for a period after the pre-charge period.

9. The method of claim 8, wherein the input signal is a digital signal.

10. The method of claim 8, further comprising driving the driving node to a negative voltage that when applied to the gate-drive node is sufficient to drive a normally-on silicon carbide junction field effect transistor to an “off” state.

11. The method of claim 8, wherein driving the driving node to a high-current state comprises enabling a first signal driver for the pre-charge period while disabling a second signal driver, each of the first and second signal drivers adapted to drive the driving node.

12. The method of claim 11, wherein driving the driving node to a controlled-current state comprises enabling the second signal driver after the pre-charge period while disabling the second first driver.

13. The method of claim 12, wherein driving the gate driving node to a controlled-current state further comprises driving the driving node through a current-limiting resistor.

14. The method of claim 8, further comprising:
applying the enable signal to a first signal driver, the enable signal controlling a respective output between enabled and disabled states;
inverting the enable signal;
applying the inverted enable signal to a second signal driver, the inverted enable signal controlling a respective output between enabled and disabled states; and
applying respective outputs of each of the first and second signal drivers to the gate-drive node.

15. A gate drive circuit, comprising:
means for receiving an input signal variable between “on” and “off” states, such variations between states occurring no sooner than a minimum signal period;
means for receiving an enable signal substantially coincident with transitions of the input signal between at least one of the “on” and “off” states, the enable signal being “on” for a pre-charge period substantially less than the minimum signal period;
means for setting a driving node to a high-current state during the pre-charge period responsive to the input signal and the enable signal; and
means for setting the gate-drive node to a controlled-current state responsive to the input signal and the enable signal for a period after the pre-charge period.
